(19) United States
(12) Patent Application Publication
(10) Pub. No.: US 2012/0280758 A1
(43) Pub. Date: Nov. 8, 2012

(54) Bulk acoustic wave resonator and method of manufacturing thereof

(75) Inventors: Antti Jaakkola, Espoo (FI); Heikki Kuisma, Vantaa (FI)

(73) Assignee: TEKNOLOGIAN TUTKIMUSKESKUS VTT, Espoo (FI)

(21) Appl. No.: 13/508,997

(22) PCT Filed: Nov. 19, 2010
(86) PCT No.: PCT/FI2010/050935

§ 371 Date: Jul. 25, 2012

(30) Foreign Application Priority Data
Nov. 19, 2009 (FI) 20096201

(51) Int. Cl. H03B 5/30; H05K 13/00

(52) U.S. Cl. 331/154; 216/13

(57) ABSTRACT

The invention concerns a novel bulk acoustic wave (BAW) resonator design and method of manufacturing thereof The bulk acoustic wave resonator comprises a resonator portion, which is provided with at least one void having the form of a trench which forms a continuous closed path on the resonator portion. By manufacturing the void in the same processing step as the outer dimensions of the resonator portion, the effect of processing variations on the resonant frequency of the resonator can be reduced. By means of the invention, the accuracy of BAW resonators can be increased.

### FIELD OF THE INVENTION

The invention relates to micromechanic resonators, in particular to bulk acoustic wave (BAW) resonators and the like.

### BACKGROUND OF THE INVENTION

The frequency of a lateral bulk-acoustic-wave mode MEMS resonator, such as a plate resonator, is defined by the lateral dimension(s) of the device. The frequency of a plate resonator operating in its square extensional (SE) mode is given to good accuracy by f=v/(2L), where v is the speed of sound and L is the length of the plate side, respectively. Due to fabrication process non-idealities, the resonator dimensions vary within a wafer and from wafer to wafer, which leads to a variation of the resonance frequency of the fabricated devices.

Typically the resonator lateral dimensions are defined with etched trenches (shown in FIG. 1a) created using, e.g., a deep reactive-ion etch (DRIE) process step. A typical variation of L can be over 1000 ppm for a 13 MHz plate resonator, which results in frequency variation that is intolerable for many applications.

As an example, let us consider a single-crystal silicon SE-plate resonator with side dimension of L˜300 μm and an operating frequency at 13 MHz). A process variation producing trenches in the range 10 . . . 11 μm (variation of 1 μm) results in a frequency variation of df˜6000 ppm. The used variation of 1 μm is used for illustrative purposes and may overestimate the typical variation of a DRIE process.

Previously, this problem has been attacked by trimming of individual components (e.g. focused-ion-beam milling), by designing the processing mask in anticipation of systematic process variation, and by measurement of the device frequency and compensation of the error by electronics. The prior methods require individual trimming or measurement of each produced resonator, which requires a lot of work or do not suit for compensating for random variations. Thus, their application in mass production is difficult or impossible. In addition, many recent applications require better frequency accuracy than the accuracy offered by these techniques.

U.S. Pat. No. 7,616,077 discloses a MEMS resonator comprising a plurality of openings which contribute to making the resonator robust to variations in manufacturing. U.S. Pat. No. 7,616,077 discloses the features of the preamble of claim 1 and is considered to represent closest prior art for the present invention.

### SUMMARY OF THE INVENTION

It is an aim of the invention to provide a novel bulk acoustic wave resonator design for compensation of the effects of process variations. In particular, it is an aim to further reduce frequency variation of BAW resonators caused by process variations. Yet another aim is to achieve a simpler process variation compensating resonator design than before.

The aim is achieved by the resonator and method as defined in the independent claims.

The invention is based on the idea of producing at least one void to a planar resonator structure. Specifically, the void is provided on the resonator portion whose dimensions define the resonating frequency(ies) of the resonator. According to the invention, the void defines a clearance, i.e. trench, between two separate portions of the resonator portion, typically an outer portion and an inner portion laterally surrounded by the outer portion. In particular, the trench may form a continuous closed path on the resonator. The void is defined by the walls of the trench.

More specifically, the invention is defined in the independent claims. Advantageous embodiments are the subject of dependent claims.

According to one embodiment, the void is a circular hole, in particular an annular (ring-shaped) hole.

According to one embodiment, the void is a rectangular hole, in particular a square hole.

In practice, the void is typically in the form of a recess produced to the resonator substrate by etching, for example. The void can also extend through the device layer of the resonator.

According to one embodiment, the recess is in the form of a trench, as described above, so that the resonator has a central elevation (inner portion) therein.

The resonator can be two-dimensional planar resonator (e.g. a square extensional (SE) plate or Lame resonator) or one-dimensional beam or bar resonator.

According to one embodiment, the void is located symmetrically with respect to at least one of the lateral central axes of the resonator portion. Preferably, the void is located symmetrically with respect to all the central axes, i.e. centrally on the resonator portion. As will be discussed later, there may be provided a plurality of separate voids, whereby these principles may be applied for the pattern of the voids.

Preferably, the void or voids is/are produced in the same processing step which is used for defining the lateral dimensions of the resonator portion. Variation in this process leads to simultaneous shrinking/growth of the plate lateral dimensions and growth/shrinking of the central void(s). In both cases, the effects counteract each other, and the resonator frequency variation is independent of the small process variations in the first order. The size and/or shape of the void are preferably optimized such that the two effects cancel each other.

Thus, the invention also provides a method comprising: providing a substrate and processing the substrate so as to produce a resonator portion having outer dimensions on the substrate. According to the invention, producing at least one void to the resonator portion occurs in the same processing step which is used for producing the outer dimensions of the resonator portion. Thus, any processing errors produced to the outer dimensions of the resonator are reproduced in a compensatory manner to the void, as will be explained later in more detail. Preferably, the processing step is an etching step, such as a deep reactive-ion etch (DRIE) step.

The invention provides significant advantages. As discussed above, the frequency accuracy of lateral bulk-mode MEMS resonators is affected by wafer-level processing inhomogeneities. By means of the invention, thus by including a void or a plurality of voids within the resonating body, frequency variation can be reduced by more than two orders of magnitude. A trench forming a continuous closed path on the resonator has proven to provide particularly low impact of process variations to the resonating frequency. By the present design, also the need of producing a plurality of separate holes placed as a symmetrical pattern to the resonator is avoided. However, generally speaking, embodiments where a plurality of trenches are provided in the resonator are not excluded either.

In more detail, our studies have shown that the frequency variation of plate and disk resonators can be decreased by a factor of 200. Variation in processing leads to simultaneous shrinking/growth of the resonator lateral dimensions and growth/shrinking of the void(s). With optimized design following the principles of the present invention, these effects cancel each other, and the resonator frequency is stabilized. For many applications, the frequency accuracy of a stabilized resonator can be at such a level that individual trimming of components can be avoided.

In practice, the present passive frequency compensation results in the improvement of the frequency accuracy of BAW resonators from the level of 1000 ppm to the level of 10 ppm and even lower.

To summarize, the main advantages of the invention include the following:
The effect of process variations on the behaviour of the resonator is significantly reduced in a self-organized manner.
There is no need for expensive trimming equipment.
The process variation does not have to be known in detail.
Measurement of all processed components is avoided and the driving integrated circuitry is simplified.

The invention can be used for all bulk acoustic wave resonator designs. Bulk Acoustic Waves (BAWs) propagate in the whole volume of the resonator. Examples are thin film bulk acoustic resonators (FBAR or TFBAR). The structure may comprise a silicon-on-insulator (SOI) structure. The resonators can be used as oscillators or sensors, for example.

The terms resonator portion and resonator plate are used to refer to the wave-guiding and resonating part of the resonator structure, the geometry of which defines the resonant frequency of the resonator. Typically, the resonator portion is planar. There may be one or more transducer elements located at the lateral sides of the resonator portion.

The term elliptical, unless otherwise indicated, covers the term circular. Similarly, the term rectangular covers the term square.

The terms void and hole refer to any structures perforating the basic material of the resonator portion. The void or hole may be vacuumed or filled with gas, such as air, or any other substance not mediating the acoustic waves produced to the resonator portion. The terms trench and clearance refer to an elongated recess or hole having a certain width.

The term lateral refers to the directions along the plane of the surface of the resonator.

Next, embodiments and of the invention and advantages thereof are discussed in more detail with reference to the attached drawings.

### BRIEF DESCRIPTION OF DRAWINGS

FIGS. 1a and 1b show schematically when an SE plate's side length L decreases as the surrounding trench grows by the trench widening parameter D. The resonator frequency f is an increasing function of D.

FIGS. 2a and 2b show schematically when only the effect of a circular void in the plate center is considered, the resonator frequency f is a decreasing function of D.

FIGS. 3a and 3b show schematically when both effects are combined, they can be made to cancel each other in first order; self-compensation takes place.

FIGS. 4a-4k show different geometrical embodiments of the invention.

FIGS. 5a and 5b show modeshapes of the extensional modes of self-compensated a) plate and b) disk resonators. The color coding denotes the total displacement (blue: small displacement, red: large displacement).

FIGS. 6a and 6b (Example 1) show a) the frequency variation of a 320-um SE plate resonator aligned in <100> direction, b) same as figure a but dimensions scaled down with a factor of 0.5.

FIGS. 7a and 7b (Example 2) show a) the frequency variation of a 320-um SE plate resonator aligned in <110> direction, b) same as figure a but dimensions scaled down with a factor of 0.5.

FIG. 8 (Example 3) shows the frequency variation of a 320-um SE plate resonator aligned in <100> direction. The central void has a shape of rectangle.

FIG. 9 (Example 4) shows the frequency variation of a 320-um SE plate resonator aligned in <110> direction. The central void has a shape of rectangle.

FIG. 10 (Example 5) shows the frequency variation of a 80-um disk polycrystalline silicon resonator. Assumed isotropic Young's modulus Y=170 Gpa, and Poisson's ratio v=0.28. The central void has a shape of circle.

### DETAILED DESCRIPTION OF EMBODIMENTS

As discussed above, the invention can be used for compensating the variations in the manufacturing process of micromechanical resonators. A void which is produced using the same process as the resonator plate itself, acts as a counterelement which compensates for dimensional inaccuracies of the structure. Thus, a any deviation of the plate lateral dimensions from the desired are compensated by a deviation of the opposite sign of the central void. In both cases, the effects counteract each other, and the resonator frequency variation is independent of the small process variations in the first order.

To give one example, the invention can be applied for silicon resonators.

In order for the changes of the void dimensions to be similar with the changes of the resonator outer dimensions, the void is preferably produced using the same manufacturing process, and, in particular, in the same step, as the outer dimensions of the resonator portion.

The trench defining the void is preferably of the same width as the trench defining the outer dimensions of the resonator. This ensures that the same processing non-idealities are repeated for the both trenches and high frequency self-compensation. However, in some designs the trenches can also be of different widths.

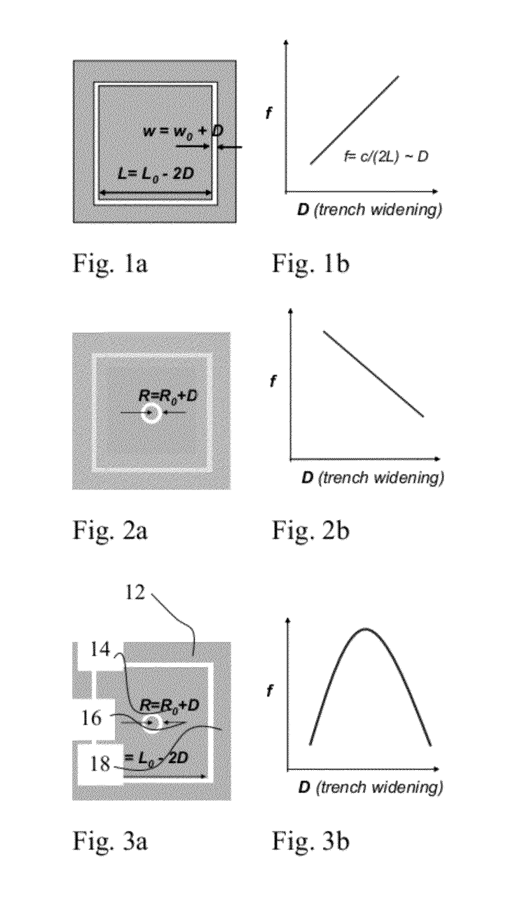

The working principle of the present passive frequency compensation according to particular embodiments is illustrated in FIGS. 1-3.

The resonator lateral dimensions are defined by a trench, whose design width is w₀—this trench will be referred to as the “outer trench”. The trench width is changed to w=w₀+D by the process variations captured by the trench widening parameter D. The variation leads to change in the resonator side length: L=L₀−2D. Since resonator frequency is given by f=c/(2L), the resonator frequency is an increasing function of D. FIGS. 1a and 1b illustrate this situation.

FIGS. 2a and 2b illustrate the effect of a circular annular void in the resonator center (the effect of the void only is now concerned, it is assumed that the plate side dimension stays constant). We assume that the void is created using a trench (hereinafter “inner trench”), which has a similar width to the outer trench. The inner trench is thus widened in a similar manner to the outer trench, and hence the circular void's radius is given by R=R₀+D. The resonator frequency is a decreasing function of D; the effective spring of the resonator is loosened as the void gets larger.

With an optimized size of the central void the two effects can be made to cancel each other in first order. Thus self-compensation takes place. FIGS. 3a and 3b illustrate this situation. Typically the void diameter has to be ˜25% of the plate side.

Referring to FIG. 3a, the substrate is denoted with reference numeral 12, the resonator portion with reference numeral 16, the outer trench separating the substrate 12 and the resonator portion 16 with reference numeral 14, and the void (inner trench) with reference numeral 18.

For example, if etched trenches define the lateral dimensions of a 13-MHz square extensional plate silicon resonator and process inhomogeneity results in a trench width variation of 1 um, this leads to ˜6000 ppm frequency variation. By including a 38-um-radius hole in the center of the plate, the frequency variation is reduced to less than 30 ppm.

The modeshape of a self-compensated SE-plate resonator can be characterized to be as a mixture of the SE-mode of the non-pierced plate and a flexural-type of vibration.

A single circular void is not the only possibility to achieve the first-order compensation effect. There are, naturally, an innumerable variety of other void geometries. One can for example use a square-shaped void, or use multiple voids for the purpose. Some possibilities are discussed below.

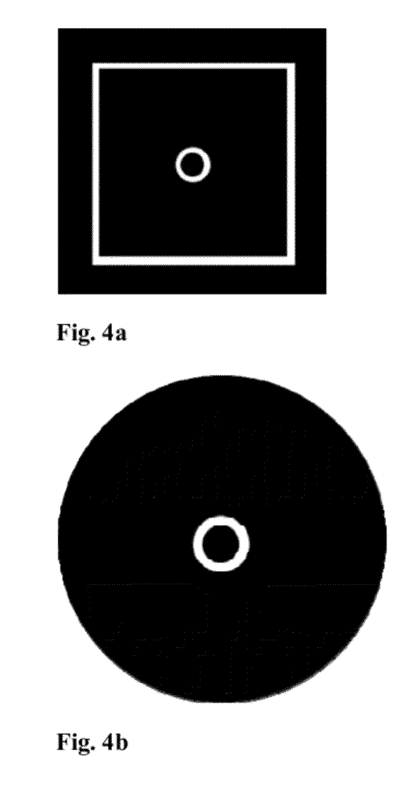

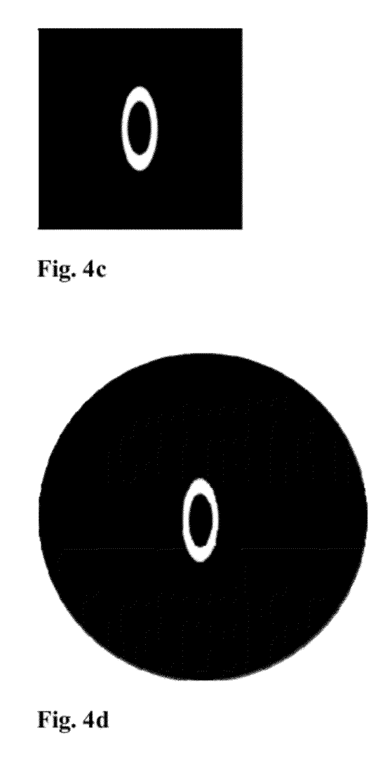

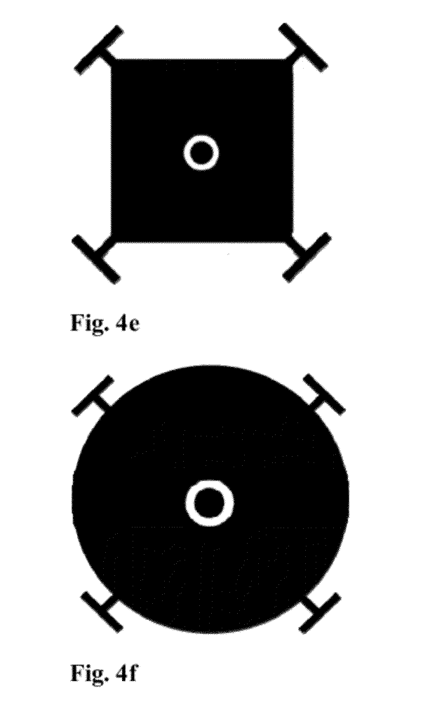

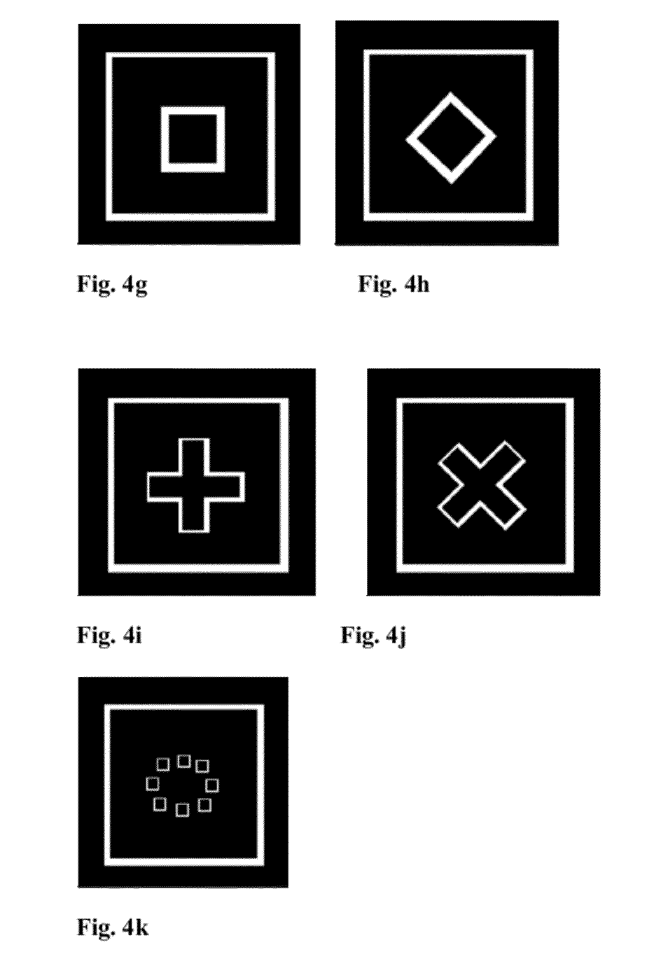

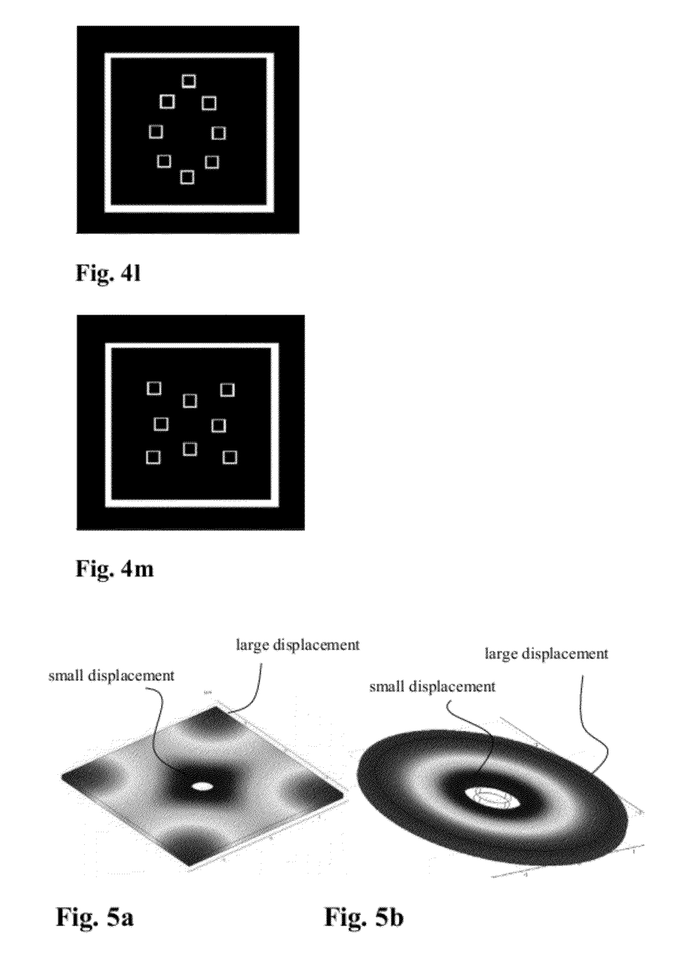

According to one embodiment of the invention, illustrated by FIGS. 4a (for rectangular plate) and 4b (for circular plate) there is provided a circular hole co-centric with the plate.

According to one embodiment (FIGS. 4c and 4d) there is provided a true elliptical (i.e. non-circular) hole co-centric with the plate.

According to one embodiment (FIGS. 4g-4j), there is provided a hole of other shape, whereby the center of gravity of the hole or holes is co-centric with the plate. For example, the hole can be rectangular or cross-shaped and oriented in any desired angle within the resonator plate.

According to one embodiment (FIGS. 4k-4m), there are provided a plurality of holes in an array, whereby the center of gravity of the array is co-centric with the plate. The array may be annular, elliptical or rectangular, for example. The shapes of the individual holes may vary.

According to one embodiment, there are provided a plurality of holes such that the density of holes is larger in the middle of the plate than at the periphery.

The outer and inner threnches may have a similar shape (e.g. both elliptical/circular or both rectangular) but they need not be.

If the void is provided in the form of a trench, it is typically of constant width.

As shown in FIGS. 4e and 4f, the resonator portions may be anchored at the resonator edges by bridges. The anchoring locations may coincide with the nodal points of a resonance mode.

Although there are many geometrical possibilities, there are certain advantages in using a single circular void in a rectangular resonator. The inner trench defining a circular void is—apart from its curvature resulting from its circular shape—similar to the straight sections of the outer trench at all of its points (it contains no corner points, for example). Therefore, it should behave during processing in a very similar manner when compared to the outer trench, and describing of the trench widening effect with a single parameter D is realistic.

With a more complicated void geometry, the trench variation of the outer trench may not be as accurately reproduced in the inner trench. For example, rounding takes place at the corners of a square-shaped void. Such a situation is challenging to model, and device design is thus more difficult.

In addition, compare 1) the dimension r1 of one representative void from a group multiple voids used for achieving self-compensation, and 2) the dimension r2 of a void, which is the single void used for self-compensation. r1 must be smaller than r2. Therefore, the relative void dimension change D/r1 is larger than the corresponding relative change D/r2. When the effects illustrated in FIGS. 1b and 2b cancel each other in first order, the higher-order terms dictate the frequency deviation. It is, in particular, the relative change of the void dimension, which defines the magnitude of the higher-order terms, and thus the frequency deviation for case 1) is larger than that of case 2).

As is apparent from the above discussion, the resonator geometry does not have to be the rectangular plate geometry. For example, the disk geometry (elliptical geometry), well studied in GHz-range polycrystalline silicon resonators, can be self-compensated using a central void. It should be noted, that the disk geometry, in particular, is not restricted to using isotropic polycrystalline materials, such as silicon; for example crystalline silicon cut in the (111) plane is isotropic within the plane, and thus disk resonators can be fabricated on (111) wafers. Other geometries apart from symmetrical plates and disks can be designed to be self-compensated.

The resonant mode of the resonator is preferably extensional. However, the invention can be used also for non-extensional modes. For example, the lame mode of a plate resonator, or the wine glass mode of the disk resonator can be self-compensated with a central void. Higher order bulk-acoustic modes can also be self-compensated, possibly by using multiple voids within the resonator body.

A self-compensated resonator geometry can be scaled up or down in size in order to change the resonator frequency. The design stays at its optimal operation point, i.e., it stays self-compensated also after the scaling operation. Such a behavior is a direct result of the scaling properties of the acoustic wave equation. The following examples illustrate the scaling behavior.

The operating frequency of the resonator can be any. In particular, the frequency can be 1 MHz-10 GHz. It has to be noted, however, that in order to reach the same level of frequency accuracy, the process variation parameter would have to be scaled in the same manner as the device dimensions. Since the process variation typically is given, and cannot be scaled simultaneously with the design, higher frequency resonators suffer from a higher frequency deviation.

A single trench widening parameter D has been used above for capturing the process variations both of the inner trench and of the outer trench. This assumption is justified, when the inner and outer trench widths are similar and trench geometries are simple (no corners or zigzag-patterns, for example).

If the trench width variation D is known as a function of the trench design width, different design widths of the inner and outer trench widths, wᵢ and wₒ, may be used. This may be advantageous if, for example, some design boundary condition requires a certain central void dimension.

To clarify this with an example, assume, that for certain choice of wᵢ and wₒ we have Dᵢ=0.5*Dₒ. In such a case the optimal void dimension is larger than that of the case when Dᵢ=Dₒ. If we interchange the roles of Dᵢ and Dₒ so that 0.5*Dᵢ=Dₒ the optimal void dimension is made smaller—this can be advantageous from the point of view that it makes the resonating mass larger.

### EXAMPLES

Different geometries were simulated using the Comsol multiphysics finite element method (FEM) software. 3D models were used, and crystalline anisotropy was included in the models when needed. Modal analysis was used to solve for the resonance modes. The relevant modeshapes of plate and disk resonators are illustrated in FIG. 5a and b, respectively.

### Example 1

### SE Plate Oriented in <100> Crystalline Direction, Circular Void

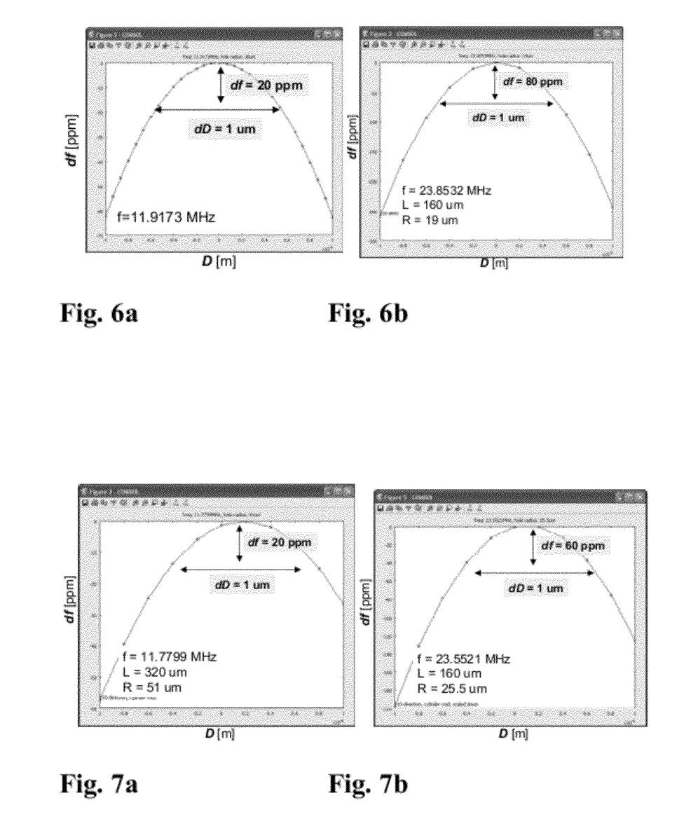

A single crystal silicon plate resonator operating in the SE mode was analyzed. The sides of the plates were aligned in the <100> crystalline directions, and the side length was L=320 μm. The optimal circular void radius is 38 um (FIG. 6a). FIG. 6b shows the frequency variation of a similar resonator with dimensions scaled down by a factor of 0.5.

### Example 2

SE plate oriented in <110> crystalline direction, circular void. Results corresponding to FIGS. 6a and 6b (plate dimensions 320 um and 160 um) are shown in FIGS. 7a and 7b.

### Example 3

SE plate oriented in <100> crystalline direction, rectangular void. Result with plate dimension 320 um is shown in FIG. 8.

### Example 4

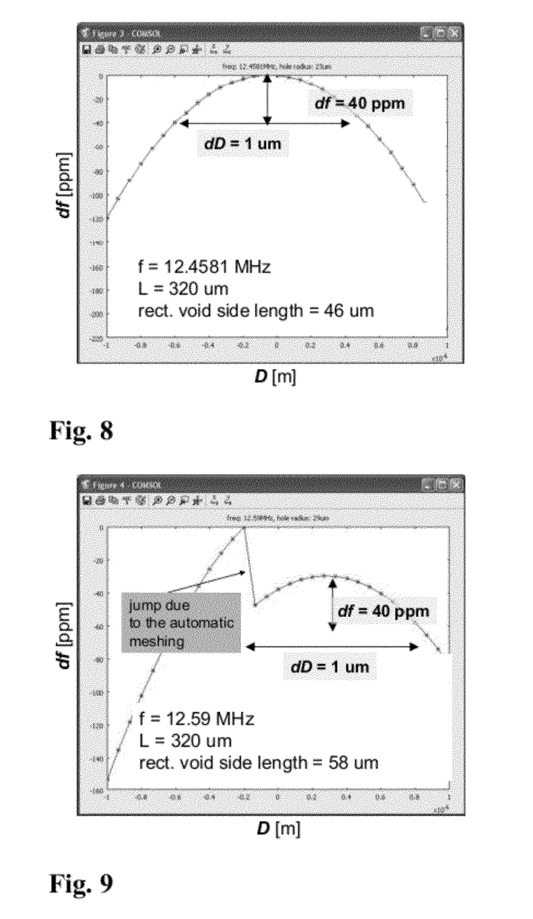

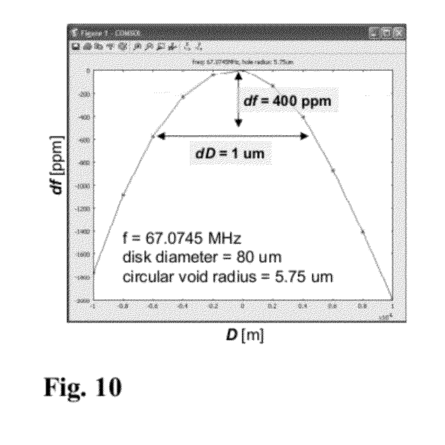

SE plate oriented in <110> crystalline direction, rectangular void. Result with plate dimension 320 um is shown in FIG. 9.

### Example 5

20 um disk resonator in polycrystalline silicon with 5.75 um central circular void. Result is shown in FIG. 9.

1. A bulk acoustic wave (BAW) resonator comprising a resonator portion, wherein there is provided at least one void within the resonator portion, and wherein the void has the form of a trench which forms a continuous closed path on the resonator portion.

2. The resonator according to claim 1, wherein the void is elliptical.

3. The resonator according to claim 1, wherein the void is rectangular.

4. The resonator according to claim 1, wherein the void is situated symmetrically with respect to at least one lateral central axis of the resonator portion.

5. The resonator according to claim 1, wherein the dimensions of the void are 15-35%, of the corresponding dimensions of the resonator portion.

6. The resonator according to claim 1, wherein there are provided a plurality of such voids on the resonator portion in a predefined pattern, the pattern preferably being symmetrical with respect to at least one central lateral axis of the resonator portion.

7. The resonator according to any of the preceding claims 1, wherein the resonator portion is rectangular or elliptical.

8. The resonator according to claim 1, wherein the resonator is comprises of a silicon wafer and a first trench manufactured on the silicon wafer, the first trench defining the resonator portion, and a second trench manufactured on the silicon wafer, the second trench defining the void.

9. The resonator according to claim 1, wherein the size and/or shape of the void is/are matched to minimize the effect of processing variations on the resonant frequency of the resonator.

10. The resonator according to claim 1, wherein the void and the outer boundaries the resonator portion are manufactured in the same processing step.

11. A method of manufacturing a bulk acoustic wave (BAW) resonator, comprising the steps of:
providing a substrate,
processing the substrate so as to produce a resonator portion having outer dimensions on the substrate, and
producing at least one void to the resonator portion in the same processing step which is used for producing the outer dimensions of the resonator portion.

12. The method according to claim 11, wherein said processing step is an etching step.

13. (canceled)

14. The method according to claim 12, wherein said etching step is a deep reactive ion etch (DRIE) step.
